(19) United States
(12) Patent Application Publication
(10) Pub. No.: US 2006/0240187 A1
(43) Pub. Date: Oct. 26, 2006

(54) Deposition of an intermediate catalytic layer on a barrier layer for copper metallization

(75) Inventor: Timothy W. Weidman, Sunnyvale, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/341,696

(22) Filed: Jan. 27, 2006

Related U.S. Application Data
(60) Provisional application No. 60/648,004, filed on Jan. 27, 2005.

(51) Int. Cl. C23C 16/00

(52) U.S. Cl. 427/248.1

(57) ABSTRACT

In one embodiment, a method for depositing a conductive material on a substrate is provided which includes exposing a substrate containing a barrier layer to a volatile reducing precursor to form a reducing layer during a soak process, exposing the reducing layer to a catalytic-metal precursor to deposit a catalytic metal-containing layer on the barrier layer, and depositing a conductive layer (e.g., copper) on the catalytic metal-containing layer. The volatile reducing precursor may include phosphine, diborane, silane, a plasma thereof, or a combination thereof and be exposed to the substrate for a time period within a range from about 1 second to about 30 seconds during the soak process. The catalytic metal-containing layer may contain ruthenium, cobalt, rhodium, iridium, nickel, palladium, platinum, silver, or copper. In one example, the catalytic metal-containing layer is deposited by a vapor deposition process utilizing ruthenium tetroxide formed by an in situ process.

### CROSS-REFERENCE TO RELATED APPLICATIONS

This application claims benefit of U.S. Ser. No. 60/648,004 (APPM/009906L), entitled “Deposition of an Intermediate Catalytic Layer on a Barrier Layer for Copper Metallization,” filed Jan. 27, 2005, which is herein incorporated by reference in its entirety.

### BACKGROUND OF THE INVENTION

1. Field of the Invention

Embodiments of the invention generally relate to methods for depositing a catalytic layer on a barrier layer prior to depositing a conductive layer thereon.

2. Description of the Related Art

Multilevel, 45 nm node metallization is one of the key technologies for the next generation of very large scale integration (VLSI). The multilevel interconnects that lie at the heart of this technology possess high aspect ratio features, including contacts, vias, lines, and other apertures. Reliable formation of these features is very important for the success of VLSI and the continued effort to increase quality and circuit density on individual substrates. Therefore, a great amount of ongoing effort is being directed to the formation of void-free features having high aspect ratios of 10:1 (height:width) or greater.

Copper is a choice metal for filling VLSI features, such as sub-micron high aspect ratio, interconnect features. Contacts are formed by depositing a conductive interconnect material, such as copper into an opening (e.g., via) on the surface of insulating material disposed between two spaced-apart conductive layers. A high aspect ratio of such an opening may inhibit deposition of the conductive interconnect material that demonstrates satisfactory step coverage and gap-fill. Although copper is a popular interconnect material, copper suffers by diffusing into neighboring layers, such as dielectric layers. The resulting and undesirable presence of copper causes dielectric layers to become conductive and electronic devices to fail. Therefore, barrier materials are used to control copper diffusion.

A typical sequence for forming an interconnect includes depositing one or more non-conductive layers, etching at least one of the layers to form one or more features therein, depositing a barrier layer within the features and depositing one or more conductive layers, such as copper, to fill the feature. The barrier layer typically includes a refractory metal nitride and/or silicide, such as titanium or tantalum. Of this group, tantalum nitride is one of the most desirable materials for use as a barrier layer. Tantalum nitride provides a good barrier to copper diffusion, even when relatively thin layers are formed (e.g., 20 Å or less). A tantalum nitride layer is typically deposited by conventional deposition techniques, such as physical vapor deposition (PVD), atomic layer deposition (ALD), and chemical vapor deposition (CVD).

Tantalum nitride does have some negative characteristics, which include poor adhesion to the copper layer deposited thereon. Poor adhesion of the subsequently deposited copper layer may lead to rapid electromigration in the formed device and increases the possibility of process contamination in subsequent process steps, such as, chemical mechanical polishing (CMP). It is believed that exposures to a source of oxygen or water may result in the oxidation of the tantalum nitride layer, thus preventing the formation of a strong bond with the subsequently deposited copper layer. The resulting interface between a tantalum nitride barrier layer and a copper layer is likely to separate during a standard tape test.

Typical deposition processes that utilize carbon-containing precursors incorporate carbon within the deposited layer. The carbon incorporation is often detrimental to the completion of wet chemical processes since the deposited film tends to be hydrophobic which reduces or prevents the fluid from wetting and depositing the desirable layer. To solve this problem, highly oxidizing processes are often used to remove the incorporated carbon, but these processes may have a detrimental effect on the other-exposed and highly oxidizable surfaces, such as, copper interconnects.

Therefore, a need exists for a method to deposit a copper-containing layer on a barrier layer with good step coverage, strong adhesion, and low electrical resistance within a high aspect ratio interconnect feature. Also, a need exists for a method to deposit a barrier layer or adhesion layer that is strongly bond to an underlayer incorporating carbon or a dielectric underlayer.

### SUMMARY OF THE INVENTION

In one embodiment, a method for depositing a conductive material on a substrate is provided which includes exposing a substrate containing a barrier layer to a volatile reducing precursor to form a reducing layer thereon, exposing the reducing layer to a catalytic-metal precursor to deposit a catalytic metal-containing layer on the barrier layer, and depositing a conductive layer on the catalytic metal-containing layer.

In one example, the barrier layer contains tantalum nitride deposited on the substrate by an atomic layer deposition (ALD) process and the reducing layer is formed within the same process chamber by a soak process, such as a vapor phase soak process. The method further provides that the volatile reducing precursor includes phosphine, diborane, silane, disilane, hydrogen, ammonia, hydrazine, derivatives thereof, plasmas thereof, or combinations thereof and that the reducing layer contains a functionalized surface of P—Hₓ, B—Hₓ, Si—Hₓ, or a derivative thereof. In another example, the reducing layer may be formed by exposing the substrate to the volatile reducing precursor for a time period within a range from about 1 second to about 30 seconds.

The catalytic metal-containing layer may contain ruthenium, cobalt, rhodium, iridium, nickel, palladium, platinum, silver, copper, alloys thereof, or combinations thereof. In one example, the catalytic metal-containing layer is deposited by a vapor deposition process using ruthenium tetroxide, ruthenocene, or a derivative thereof as the catalytic-metal precursor. The ruthenium tetroxide may be formed during an in situ process by exposing ruthenium metal to an oxidizer, such as ozone. In another example, the catalytic metal-containing layer is deposited by a liquid deposition process using ruthenium chloride, cobalt chloride, palladium chloride, or platinum chloride as the catalytic-metal precursor. Generally, the conductive layer contains copper, nickel, cobalt, tungsten, tantalum, or an alloy thereof.

In another embodiment, a method for depositing a conductive material on a substrate is provided which includes exposing a substrate containing an oxide layer to a reactive plasma process, exposing the substrate to ruthenium tetroxide during a vapor deposition process to deposit a catalytic metal-containing layer on the substrate, and depositing a conductive layer on the catalytic metal-containing layer. In one example, the substrate is exposed to a reactive soak compound is derived from a precursor, such as phosphine, diborane, silane, a plasma thereof, a derivative thereof, or a combination thereof during the reactive plasma process.

In another embodiment, a method for depositing a conductive material on a substrate is provided which includes exposing a substrate containing a barrier layer to a volatile reducing precursor to form a phosphorus-containing reducing layer thereon, and exposing the phosphorus-containing reducing layer to a catalytic-metal precursor to deposit a ruthenium-containing layer on the barrier layer.

In another embodiment, a method for depositing a conductive material on a substrate is provided which includes exposing a substrate containing a barrier layer to a volatile reducing precursor during a soak process, depositing a catalytic metal-containing layer on the barrier layer, wherein the catalytic metal-containing layer contains ruthenium, cobalt, rhodium, iridium, nickel, palladium, platinum, silver, copper, an alloy thereof, or a combination thereof, and depositing a conductive layer on the catalytic metal-containing layer.

In another embodiment, a method for depositing a conductive material on a substrate is provided which includes exposing a substrate containing a barrier layer to a volatile reducing precursor during a soak process, exposing the substrate to a catalytic-metal precursor to deposit a catalytic metal-containing layer on the barrier layer during a vapor deposition process, and depositing a conductive layer on the catalytic metal-containing layer.

In another embodiment, a method for depositing a conductive material on a substrate is provided which includes exposing a substrate containing a barrier layer to a volatile reducing precursor during a soak process, and exposing the substrate to a catalytic-metal precursor to deposit a catalytic metal-containing layer on the barrier layer during a liquid deposition process, and depositing a conductive layer on the catalytic metal-containing layer.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1A depicts a process sequence according to one embodiment described herein;

FIG. 1B depicts another process sequence according to one embodiment described herein;

FIGS. 2A-2F illustrate schematic cross-sectional views of an integrated circuit fabrication sequence formed by a process described herein;

FIGS. 3A-3E illustrate schematic cross-sectional views of integrated circuit fabrication sequence formed by another process described herein;

FIG. 4 illustrates a cross-sectional view of a capacitively coupled plasma processing chamber that may be adapted to perform an embodiment described herein;

FIGS. 5A and 5B illustrate a cross-sectional view of another process chamber that may be adapted to perform an embodiment described herein;

FIGS. 6A and 6B illustrate a cross-sectional view of another process chamber that may be adapted to perform an embodiment described herein; and

FIGS. 7A and 7B illustrate a cross-sectional view of another process chamber that may be adapted to perform an embodiment described herein.

### DETAILED DESCRIPTION OF THE PREFERRED EMBODIMENT

A method for depositing multiple layers of materials to form electronic devices is disclosed herein. Generally, the method includes exposing a substrate surface to a gas, liquid or vapor to form a catalytic layer. The catalytic layer reduces electromigration and allows the features on the substrate surface to be filled with a desired metal, such as by an electroless plating process, an electroplating process, a chemical vapor deposition (CVD) process, or an atomic layer deposition (ALD) process. Due to electromigration and other device processing concerns, a process is described herein that includes depositing a barrier layer and a catalytic-metal layer, strongly bonded on the exposed substrate surface.

In one embodiment, the method includes depositing a barrier layer on a substrate surface, exposing the barrier layer to a soak process to form a reducing layer, depositing a catalytic layer on the barrier layer by exposing the reducing layer to a catalytic metal-containing precursor and depositing a conductive layer on the catalytic layer. The term “soak process” is intended to describe a thermally activated process or a RF plasma process for forming a reducing layer by exposing a substrate to a reagent within a gas phase, a liquid phase, a vapor phase or a plasma phase. The soak process may be performed prior to, during, or subsequent to a CVD process, an ALD process, a plasma-enhanced CVD (PE-CVD) process, a high density plasma CVD (HDP-CVD) process, or a plasma-enhanced ALD (PE-ALD) process. Preferably, the barrier layer (e.g., tantalum nitride) is deposited by an ALD process. The barrier layer is exposed to a reducing gas during the soak process that may include phosphine, diborane or silane. A reducing layer is formed on the barrier layer, generally functionalized with a reducing group (e.g., P—Hₓ, B—Hₓ or Si—Hₓ) derived from a volatile reducing precursor. The reducing layer is exposed to a catalytic metal-containing precursor to deposit a catalytic layer on the barrier layer. In one example, the catalytic metal-containing precursor is exposed to the substrate during a liquid deposition process. In another example, the catalytic metal-containing precursor is exposed to the substrate during a vapor phase deposition process. The deposited catalytic layer contains a catalytic metal that may include ruthenium, cobalt, rhodium, iridium, nickel, palladium, platinum, silver, copper, alloys thereof, or combinations thereof. Thereafter, a conductive layer is deposited on the catalytic layer. For example, the conductive layer may be a copper or ruthenium seed layer, copper-containing bulk layer or secondary barrier layer, such as a cobalt tungsten phosphide layer.

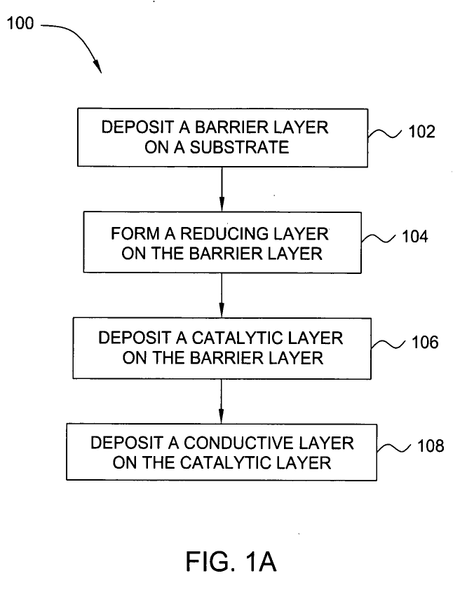

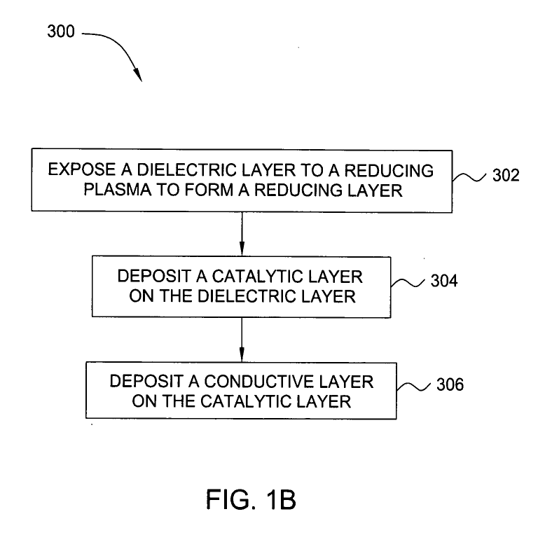

FIG. 1A depicts process 100 according to one embodiment described herein for fabricating an integrated circuit. A metal-containing barrier layer is deposited on a substrate surface during step 102. In step 104, a reducing layer is formed on the barrier layer by exposing the substrate to a volatile reducing precursor during a soak process. The reducing layer has a chemically reducing functionality. Subsequently, the reducing layer is exposed to catalytic metal precursor to deposit a catalytic layer on the barrier layer during step 106. Thereafter, a conductive layer is deposited on the catalytic layer during step 108.

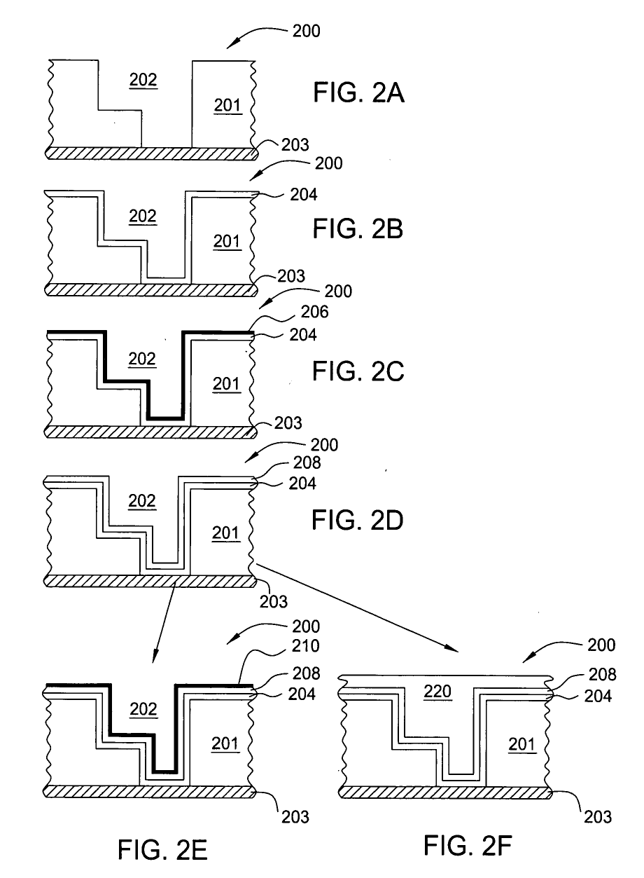

Process 100 corresponds to FIGS. 2A-2F by illustrating schematic cross-sectional views of an electronic device at different stages of an interconnect fabrication sequence incorporating one embodiment of the invention. FIG. 2A illustrates a cross-sectional view of substrate 200 having a via or an aperture 202 formed into a dielectric layer 201 on the surface of the substrate 200. Substrate 200 may contains a semiconductor material, such as silicon, germanium, or silicon germanium. The dielectric layer 201 may be an insulating material such as, silicon oxide, silicon nitride, silicon oxynitride, fluorine-doped silicate glass (FSG), or carbon-doped silicon oxides, such as SiOₓC_{y}, for example, BLACK DIAMOND® low-k dielectric, available from Applied Materials, Inc., located in Santa Clara, Calif. Aperture 202 may be formed in dielectric-layer 201 using conventional lithography and etching techniques to expose contact layer 203. Contact layer 203 may include copper, tungsten, aluminum, or an alloy thereof.

Barrier-Layer Formation

Barrier layer 204 may be formed on the dielectric layer 201 and in aperture 202, as depicted in FIG. 2B. Barrier layer 204 may include one or more barrier materials, such as tantalum, tantalum nitride, tantalum silicon nitride, titanium, titanium nitride, titanium silicon nitride, tungsten nitride, silicon nitride, silicon carbide, derivatives thereof, alloys thereof, or combinations thereof. Barrier layer 204 may be formed using a suitable deposition process including ALD, PE-ALD, CVD, PE-CVD, physical vapor deposition (PVD), or combinations thereof. For example, a tantalum nitride barrier layer may be deposited from a tantalum precursor (e.g., PDMAT) and a nitrogen precursor (e.g., ammonia) during a CVD process or an ALD process. In another example, tantalum and/or tantalum nitride are deposited as barrier layer 204 by an ALD process as described in commonly assigned U.S. Ser. No. 10/281,079, entitled “Gas. Delivery Apparatus for Atomic Layer Deposition,” filed Oct. 25, 2002, and published as US 2003-0121608, which is herein incorporated by reference in its entirety. In one example, a Ta/TaN bilayer may be deposited as barrier layer 204, wherein the tantalum layer and the tantalum nitride layer are independently deposited by ALD, PE-ALD, CVD, PE-CVD, and/or PVD processes. Further disclosure of processes for depositing a material or multiple materials as a barrier layer or another layer is described in commonly assigned U.S. Ser. No. 10/052,681, entitled “Reliability Barrier Integration for Cu Application,” filed Jan. 17, 2002, and published as US 2002-0060363, in commonly assigned U.S. Pat. No. 6,951,804, in commonly assigned U.S. Ser. No. 10/199,415, entitled “Enhanced Copper Growth with Ultrathin Barrier Layer for High Performance Interconnects,” filed Jul. 18, 2002, and published as US 2003-0082301, and in commonly assigned U.S. Ser. No. 10/865,042, entitled “Integration of ALD Tantalum Nitride for Copper Metallization,” filed Jun. 10, 2004, and published as US 2005-0106865, which are all herein incorporated by reference in their entirety.

Generally, barrier layer 204 is deposited having a film thickness within a range from about 5 Å to about 150 Å, preferably, from about 5 Å to about 50 Å, such as about 20 Å. In one example, barrier layer 204 is deposited within aperture 202 on a sidewall with a thickness of about 50 Å or less, preferably, about 20 Å or less, such as about 10 Å or less. A tantalum nitride barrier layer having a thickness of about 20 Å or less is believed to be a sufficient for preventing diffusion of subsequently deposited metals, such as copper.

Examples of tantalum precursors that may be used during a vapor deposition process to form barrier layers, as described herein include pentakis(dimethylamino) tantalum (PDMAT or Ta[NMe₂]₅), pentakis(ethylmethylamino) tantalum (PEMAT or Ta[N(Et)Me]₅), pentakis(diethylamino) tantalum (PDEAT or Ta(NEt₂)₅,), tertiarybutylimino-tris(dimethylamino) tantalum (TBTDMT or (^{t}BuN)Ta(NMe₂)₃), tertiarybutylimino-tris(diethylamino) tantalum (TBTDET or (^{t}BuN)Ta(NEt₂)₃), tertiarybutylimino-tris(ethylmethylamino) tantalum (TBTEAT or (^{t}BuN)Ta[N(Et)Me]₃), tertiaryamylimido-tris(dimethylamido) tantalum (TAIMATA or (^{t}AmylN)Ta(NMe₂)₃, wherein ^{t}Amyl is the tertiaryamyl group (C₅H₁₁— or CH₃CH₂C(CH₃)₂—), tertiaryamylimido-tris(diethylamido) tantalum (TAIEATA or (^{t}AmylN)Ta(NEt₂)₃, tertiaryamylimido-tris(ethylmethylamido) tantalum (TAIMATA or (^{t}AmylN)Ta([N(Et)Me]₃), tantalum halides, such as TaF₅ or TaCl₅, derivatives thereof, or combinations thereof. Examples of nitrogen precursors that are useful during the vapor deposition process to form a barrier layer, include, but are not limited to precursors such as ammonia (NH₃), hydrazine (N₂H₄), methylhydrazine (Me(H)NNH₂), dimethyl hydrazine (Me₂NNH₂ or Me(H)NN(H)Me), tertiarybutylhydrazine (^{t}Bu(H)NNH₂), phenylhydrazine (C₆H₅(H)NNH₂), a nitrogen plasma source (e.g., N, N₂, N₂/H₂, NH₃, or a N₂H₄ plasma), 2,2′-azotertbutane (^{t}BuNN^{t}Bu), an azide source, such as ethyl azide (EtN₃), trimethylsilyl azide (Me₃SiN₃), derivatives thereof, or combinations thereof.

The tantalum nitride barrier layer 204 may be deposited during an ALD process that adsorbs a layer of a tantalum precursor on the substrate followed by exposing the substrate to a nitrogen precursor. Alternatively, the ALD process may start by adsorbing a layer of the nitrogen precursor on the substrate followed by exposing the substrate to the tantalum precursor. Furthermore, the process chamber is usually evacuated between pulses of reactant gases.

An exemplary process of depositing a tantalum nitride barrier layer 204 by an ALD process that provides PDMAT having a flow rate within a range from about 20 sccm to about 1,000 sccm, preferably, from about 100 sccm to about 400 sccm and exposing the substrate for a time period of about 2 seconds or less, preferably, within a range from about 0.05 seconds to about 1 second, more preferably, from about 0.1 seconds to about 0.5 seconds. Ammonia may be provided having a flow rate within a range from about 20 sccm and about 1,000 sccm, preferably, from about 200 sccm to about 600 sccm and exposing the substrate for a time period of about 1 second or less, preferably within a range from about 0.05 seconds to about 0.5 seconds. An argon purge gas may have a flow rate within a range from about 100 sccm to about 1,000 sccm, preferably, from about 100 sccm to about 400 sccm, may be continuously provided or pulsed into the process chamber. The time between pulses of the tantalum precursor and the nitrogen precursor may be about 5 seconds or less, preferably, within a range from about 0.5 seconds to about 2 seconds, more preferably, from about 0.5 seconds to about 1 second. The substrate is may be heated at a temperature within a range from about 50° C. to about 350° C.,. preferably, from about 100° C. to about 300° C. and the chamber may be pressurized at a pressure within a range from about 0.05 Torr to about 50 Torr.

Embodiments of the ALD process have been described above as adsorption of a monolayer of reactants on a substrate. Other aspects of the invention include examples in which the reactants are deposited on a surface with a thickness more or less than a monolayer. The invention also includes examples in which deposition occurs in mainly a chemical vapor deposition process in which the reactants are sequentially or simultaneously delivered. Embodiments of cyclical deposition have been described above as the deposition of a binary compound of tantalum nitride utilizing pulses of two reactants. In the deposition of other elements or compounds, pulses of two or more reactants may also be used. For example, an ALD process for the tertiary compound tantalum silicon nitride utilizes pulses of tantalum, silicon, and nitrogen precursors.

Reducing Layer Formation

Process 100 further includes step 104 to promote strong adhesion by forming reducing layer 206 on barrier layer 204, as depicted in FIG. 2C. The substrate surface is exposed to a volatile reducing precursor to form reducing layer 206 during a soak process. The volatile reducing precursor may include borane, diborane, borane-alkylsulfides, such as borane-dimethylsulfide (BH₃:(CH₃)₂S), alkyboranes (e.g., ethylborane), phosphine, alkylposphines (e.g., dimethylphosphine), silane, disilane, trisilane, alkylsilanes (e.g., methylsilane), ammonia, hydrazine, hydrogen, complexes thereof, derivatives thereof, plasmas thereof, or combinations thereof. Preferably, the volatile reducing precursor is diborane, phosphine, silane, hydrazine, hydrogen, or combinations thereof. Reducing layer 206 may contain the chemically reducing functional group of B—Hₓ, P—Hₓ, Si—Hₓ or N—Hₓ, wherein x is within a range from about 1 to about 3. For example, when a soak process includes diborane, phosphine, or silane, reducing layer 206 will generally be functionalized to respectively contain B—Hₓ, P—Hₓ, or Si—Hₓ groups.

Substrate 200 and barrier layer 204 is exposed to the volatile reducing precursor during a soak process for a pre-determined time to form reducing layer 206. The soak process may occur for about 5 minutes or less, such as a time period within a range from about 1 second to about 120 seconds, preferably, from about 1 second to about 90 seconds, and more preferably, from about 1 second to about 30 seconds. During the soak process, the substrate is heated at a temperature within a range from about 20° C. to about 350° C., depending on the reactivity of the volatile reducing precursor. The process chamber may be pressurized at a pressure within a range from about 0.1 Torr to about 750 Torr, preferably, from about 0.1 Torr to about 100 Torr.

The volatile reducing precursor may be exposed to barrier layer 204 directly or diluted in a carrier gas. During the soak process in step 104, a carrier gas flow is established within the process chamber and exposed to the substrate. Carrier gases may be selected so as to also act as a purge gas for-the removal of volatile reactants and/or by-products from the process chamber. Carrier gases or purge gases include helium, argon, nitrogen, hydrogen, forming gas, or a combination thereof. The carrier gas may be provided at a flow rate within a range from about 100 sccm to about 5,000 sccm, preferably from about 500 sccm to about 2,500 sccm. The volatile reducing precursor may be provided at a flow rate within a range from about 5 sccm to about 500 sccm, preferably, from about 10 sccm to about 100 sccm.

The soak process in step 104 may be conducted in a process chamber capable of vapor deposition. In one example, step 104 is conducted within the same process chamber used to deposit barrier layer 204 in step 102. In another example, step 104 is conducted within the same process chamber used to deposit catalytic layer 208 as described in step 106. Furthermore, in another example, the substrate may be transferred into an additional process chamber while maintaining a reduced atmosphere prior to the soak process. Preferably, the soak process in step 104 is conducted within an ALD process chamber subsequent to depositing a barrier layer in the same ALD process chamber.

In an exemplary soak process, a substrate is heated to about 300° C. and the process chamber is pressurized at a pressure of about 2 Torr. The substrate is exposed to a reducing gas having a flow rate of about 600 sccm, whereas the reducing gas contains a volatile reducing precursor (e.g., phosphine, diborane, or silane) with a flow rate of about 300 sccm and a carrier gas with a flow rate of about 300 sccm. In one example, the volatile reducing precursor contains 5 vol % of phosphine in argon having a flow rate of about 300 sccm and a hydrogen carrier gas having a flow rate of about 300 sccm. The substrate is exposed to the reducing gas for about 15 seconds to form a reducing layer containing a layer of P—Hₓ functional groups on the barrier layer.

In another exemplary soak process, a substrate is heated to about 250° C. and the process chamber is pressurized at a pressure of about 2 Torr. The substrate is exposed to the reducing gas containing phosphine for about 10 seconds or less to form a reducing layer containing a layer of P—Hₓ functional groups on the barrier layer.

In an alternative embodiment of step 104, a reducing layer is formed on barrier layer 204 during a plasma soak process. The plasma soak process includes exposing barrier layer 204 to a reducing plasma (i.e., a volatile reducing precursor or derivative thereof in the plasma state of matter) to form a reducing layer. The volatile reducing precursor in a plasma state may include borane, diborane, alkyboranes (e.g., ethylborane), phosphine, alkylposphines (e.g., dimethylphosphine), silane, disilane, trisilane, alkylsilanes (e.g., methylsilane), ammonia, hydrazine, hydrogen, ions thereof, derivatives thereof, or combinations thereof. Preferably, the volatile reducing precursor is silane, diborane, phosphine, or a combination thereof. Reducing layer 206 may contain a layer of a chemically reducing molecular group, such as Si—Si, B—B, P—P, Si—Hₓ, B—He and/or P—Hₓ. For example, when a plasma soak process includes phosphine, reducing layer 206 formed on the barrier layer 204 will generally be functionalized to generate P—P, P—H and/or PH₂ functionality at the substrate surface.

Further disclosure or processes for depositing a material or multiple materials as a barrier layer or another layer is described in commonly assigned U.S. Ser. No. 10/052,681, entitled “Reliability Barrier Integration for Cu Application,” filed Jan. 17, 2002, and published as US 2002-0060363, in commonly assigned U.S. Pat. No. 6,951,804, in commonly assigned U.S. Ser. No. 10/199,415, entitled “Enhanced Copper Growth with Ultrathin Barrier Layer for High Performance Interconnects,” filed Jul. 18, 2002, and published as US 2003-0082301, and in commonly assigned U.S. Ser. No. 10/865,042, entitled “Integration of ALD Tantalum Nitride for Copper Metallization,” filed Jun. 10, 2004, and published as US 2005-0106865, which are all herein incorporated by reference in their entirety.

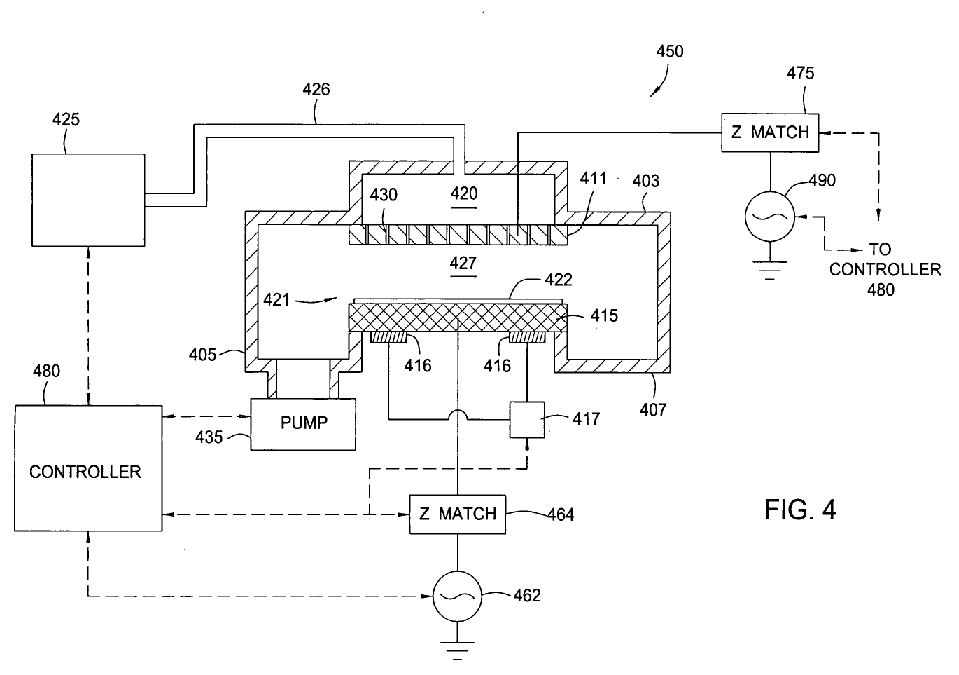

The plasma soak process in step 104 may be conducted in a process chamber capable of plasma vapor deposition techniques. For example, the substrate may be placed into a plasma-enhanced ALD (PE-ALD) a plasma-enhanced CVD (PE-CVD) or high density plasma CVD (HDP-CVD) chamber, such as the ULTIMA HDP-CVD®, available from Applied Materials, Inc., located in Santa Clara, Calif. Other process chambers and processes that may be used during thermal or plasma-enhanced vapor deposition processes as described herein include commonly assigned U.S. Pat. Nos. 6,878,206, 6,916,398, 6,936,906, commonly assigned U.S. Ser. No. 10/281,079, entitled “Gas Delivery Apparatus for Atomic Layer Deposition,” filed Oct. 25, 2002, and published as US 2003-0121608, commonly assigned U.S. Ser. No. 10/197,940, entitled “Apparatus and Method for Plasma Assisted Deposition,” filed Jul. 16, 2002, and published as US 2003-0143328, and commonly assigned U.S. Ser. Nos. 60/733,574, 60/733,654, 60/733,655, 60/733,869, 60/733,870, each entitled “Apparatus and Process for Plasma-Enhanced Atomic Layer Deposition,” and each filed Nov. 4, 2005, are all herein incorporated by reference in their entirety. FIG. 4, described below, illustrates one embodiment of a capacitively coupled plasma chamber that may be useful for performing the plasma soak process described in step 302. In other aspects of the invention an inductively coupled plasma generating device, capacitively coupled plasma generating device, or combination thereof may be used in a plasma chamber to carryout the plasma soak process.

Substrate 200 and barrier layer 204 are exposed to the plasma soak process for a pre-determined time to form reducing layer 206. The plasma soak process may occur for about 5 minutes or less, such as within a range from about 1 second to about 60 seconds, preferably, from about 1 second to about 30 seconds. During the soak process, the substrate is maintained at a temperature within a range from about 20° C. to about 350° C., preferably, from about 50° C. to about 250° C. The process chamber is pressurized at a pressure within a range from about 0.1 Torr to about 10 Torr.

Barrier layer 204 is exposed to a reducing plasma containing the volatile reducing precursor to form reducing layer 206. The reductant is preferably diluted in a carrier gas. During the plasma soak process in step 104, a carrier gas flow is established within the process chamber and exposed to the substrate. Carrier gases may be selected so as to also act as a purge gas for the removal of volatile reactants and/or by-products from the process chamber. Carrier gases or purge gases include helium, argon, hydrogen, forming gas, or a combination thereof. The carrier gas may be provided at a flow rate within a range from about 500 sccm to about 5,000 sccm, preferably, from about 500 sccm to about 2,500 sccm. The volatile reducing precursor may be provided at a flow rate within a range from about 5 sccm to about 500 sccm, preferably from about 10 sccm to about 100 sccm. The plasma may be formed using an RF power delivered to the plasma generating devices (e.g., showerhead 411 in a capacitively coupled chamber 450, a substrate pedestal 415) utilized within the plasma chamber. Generally, the plasma chamber may be set during a plasma soak process to have a RF power within a range from about 100 watt to about 10,000 watt and have an RF frequency within a range from about 0.4 kHz to about 10 GHz. In one example, the plasma is formed using a showerhead RF power setting and a substrate support RF power setting that is within a range from about 500 watt to about 5,000 watt at a frequency of about 13.56 MHz.

In an exemplary plasma soak process, the substrate is heated to about 50° C. and the process chamber is pressurized at a pressure of about 2 Torr. The substrate is exposed to a reducing plasma having a flow rate of about 1,000 sccm, whereas the reducing plasma contains phosphine with a flow rate of about 200 sccm and a helium carrier gas with the flow rate of about 800 sccm. The substrate is exposed to the reducing plasma for about 60 seconds to form a reducing layer containing a layer of P—P and P—Hₓ functional groups on the barrier layer.

In an exemplary plasma soak process, the substrate is heated to about 50° C. and the process chamber is maintained at a pressure of about 2 Torr. The substrate is exposed to a reducing plasma having a flow rate of about 500 sccm, whereas the reducing plasma contains silane having a flow rate of about 50 sccm and a helium carrier gas having a flow rate of about 450 sccm. The substrate is exposed to the reducing plasma for about 10 seconds to form a reducing layer containing a layer of Si—Si and Si—Hₓ functional groups on the barrier layer.

Catalytic Layer formation

In step 106, a catalytic layer 208 is deposited on barrier layer 204 as depicted in FIG. 2D. Catalytic layer 208 is formed by exposing reducing layer 206 to a catalytic metal-containing precursor. Reducing layer 206 chemically reduces the catalytic metal-containing precursor to form catalytic layer 208 on barrier layer 204 containing the respective metal from the precursor. Catalytic layer 208 exhibits good adhesion to metal layers deposited onto the catalytic layer, such as copper, and also exhibits good adhesion to the oxidized remnants of the reducing layer 206. In one example, the catalytic metal-containing precursor is delivered to reducing layer 206 by a vapor deposition process, such as an ALD process or a CVD process. Alternatively, in another example, the catalytic metal-containing precursor is delivered to reducing layer 206 by a liquid deposition process, such as an aqueous solution containing the precursor dissolved therein.

Catalytic layer 208 includes at least one catalytic metal and usually contains the oxidized remnants of the reducing layer 206. The catalytic metal may include ruthenium, cobalt, rhodium, iridium, nickel, palladium, platinum, copper, silver, alloys thereof, or combinations thereof. Generally, the chemical reaction between reducing layer 206 and the catalytic metal-containing precursor forms the metallic form of the catalytic metal (e.g., Ru⁰ or Co⁰) and/or the respective boride, phosphide, silicide, nitride, or combinations thereof. Therefore, catalytic layer 208 may contain ruthenium, ruthenium boride, ruthenium phosphide, ruthenium silicide, ruthenium nitride, copper, cobalt, cobalt boride, cobalt phosphide, cobalt silicide, cobalt nitride, rhodium, rhodium boride, rhodium phosphide, rhodium silicide, rhodium nitride, iridium, iridium boride, iridium phosphide, iridium silicide, iridium nitride, nickel, nickel boride, nickel phosphide, nickel silicide, nickel nitride, palladium, palladium boride, palladium phosphide, palladium silicide, palladium nitride, platinum, platinum boride, platinum phosphide, platinum silicide, platinum nitride, derivatives thereof, alloys thereof, or combinations thereof. Catalytic layer 208 is deposited and has a thickness within a range from about an atomic layer to about 100 Å, preferably, from about 1 Å to about 50 Å, and more preferably, from about 2 Å to about 20 Å. The catalytic layer adheres to the barrier layer as well as the subsequent conductive layer, such as a seed layer or a bulk layer.

During a vapor deposition process, the catalytic metal-containing precursor is vaporized and exposed to reducing layer 206. The vapor deposition process is conducted at a temperature high enough to vaporize the catalytic metal-containing precursor and drive the reduction reaction to completion. However, the process temperature should be low enough not to cause the catalytic metal-containing precursor to non-selectively decompose, such as on the process chamber interior. The temperature range varies according to the particular catalytic metal-containing precursor used during the deposition. Generally, the temperature is heated within a range from about 25° C. to about 350° C., preferably, from about 50° C. to about 250° C. The process chamber may be a typical vapor deposition chamber as used during ALD, CVD, or PVD processes. The process chamber is maintained at a pressure relative to the temperature, precursor and particular process. Generally, the pressure is maintained within a range from about 0.05 Torr to about 750 Torr, preferably, from about 0.1 Torr to about 10 Torr. The catalytic metal-containing precursor is exposed to reducing layer 206 for a predetermined time interval within a range from about 0.1 seconds to about 2 minutes, preferably, from about 1 second to about 60 seconds, and more preferably, from about 1 second to about 30 seconds. The catalytic metal-containing precursor may be delivered purely or diluted in a carrier gas that includes nitrogen, hydrogen, argon, helium or combinations thereof.

Catalytic metal-containing precursors may include ruthenium-containing precursors, such as ruthenium oxides, ruthenocene compounds and ruthenium compounds containing at least one open chain dienyl ligand. The preferred ruthenium oxide compound is ruthenium tetroxide (RuO₄). Ruthenium tetroxide may be prepared using an in situ generation process by exposing a metallic ruthenium source to an oxidizing gas, such as ozone. The in situ generated ruthenium tetroxide is immediately introduced into the process chamber. Ruthenium tetroxide is a strong oxidant which readily reacts with the reducing layer to form a ruthenium-containing catalytic layer on the barrier layer. Advantages that are realized due to the extremely reactive nature of ruthenium tetroxide include the ability to form strong bonds with most functional groups found on dielectric materials and the ability to non-selectively deposit at temperatures greater than 200° C.

In one example, ruthenium tetroxide may be formed by heating ruthenium metal to a temperature within a range from about 20° C. to about 100° C. and exposing the ruthenium metal to ozone gas. A gas mixture containing ozone may be generated by flowing oxygen through an ozone generator. Preferably, the gas mixture contains about 12 vol % or more of ozone within oxygen. The ozone may be separated from the oxygen gas by exposing the mixture to a silica gel at a low temperature to adsorb the ozone. Subsequently, the ozone is exposed to a metallic ruthenium source maintained at about 40° C. to form ruthenium tetroxide. The ruthenium tetroxide is condensed into a cold trap and maintained at a temperature within a range from about −80° C. to 0° C. After the accumulation of at least enough ruthenium tetroxide to perform a single deposition step, the ozone flow is stopped and the cold trap is purged with an inert gas (e.g., nitrogen) to rid of any excess oxygen or ozone from the line and the ruthenium metal source region. Thereafter, the cold trap is warmed to a temperature within a range from about 0° C. to about 50° C. and a flow of inert gas is passed therethrough.

In an exemplary vapor deposition process, the deposition gas, containing ruthenium tetroxide, is then delivered to the surface of the substrate having a reducing layer containing P—H functional groups formed thereon. The reducing layer containing P—H functional groups may be formed by use of a phosphine soak process or phosphine plasma soak process. During the process the substrate is maintained at a temperature of about 100° C. After exposing the reducing layer to the ruthenium tetroxide containing gas for about 10 seconds to produce a ruthenium dioxide (RuO₂) based catalytic layer on the barrier layer. One embodiment of a ruthenium tetroxide generation apparatus and method for creating and depositing a ruthenium layer is further described below in conjunction with FIGS. 8A-B.

In another aspect of step 106, a CVD or ALD process using a ruthenium precursor is used to form the catalytic layer on the reducing layer. Other ruthenium precursors that are useful for forming ruthenium containing catalytic layers are ruthenocene compounds that contain at least one cyclopentyl ligand such as RₓC₅H₅₋ₓ, where x=0-5 and R is independently hydrogen or an alkyl group and include bis(cyclopentadienyl) ruthenium compounds, bis(alkylcyclopentadienyl) ruthenium compounds, bis(dialkylcyclopentadienyl) ruthenium compounds, or derivatives thereof, where the alkyl groups may be independently methyl, ethyl, propyl, or butyl. A bis(cyclopentadienyl) ruthenium compound has a generic chemical formula (RₓC₅H₅₋ₓ)₂Ru, where x=0-5 and R is independently hydrogen or an alkyl group such as methyl, ethyl, propyl, or butyl. Ruthenium precursors may also contain at least one open chain dienyl ligand such as CH₂CRCHCRCH₂, where R is independently an alkyl group or hydrogen. In some examples, the ruthenium-containing precursor may have two open-chain dienyl ligands, such as pentadienyl or heptadienyl and include bis(pentadienyl) ruthenium compounds, bis(alkylpentadienyl) ruthenium compounds and bis(dialkylpentadienyl) ruthenium compounds. A bis(pentadienyl) ruthenium compound has a generic chemical formula (CH₂CRCHCRCH₂)₂Ru, where R is independently an alkyl group or hydrogen. Usually, R is independently hydrogen, methyl, ethyl, propyl, or butyl. Also, ruthenium-containing precursor may have both an open-chain dienyl ligand and a cyclopentadienyl ligand.

Therefore, examples of ruthenium-containing precursors useful during vapor deposition processes described herein include ruthenium tetroxide, bis(cyclopentadienyl) ruthenium (Cp₂Ru), bis(methylcyclopentadienyl) ruthenium, bis(ethylcyclopentadienyl) ruthenium, bis(penfamethylcyclopentadienyl) ruthenium, bis(2,4-dimethylpentadienyl) ruthenium, bis(2,4-diethylpentadienyl) ruthenium, bis(2,4-diisopropylpentadienyl) ruthenium, bis(2,4-ditertbutylpentadienyl) ruthenium, bis(methylpentadienyl) ruthenium, bis(ethylpentadienyl) ruthenium, bis(isopropylpentadienyl) ruthenium, bis(tertbutylpentadienyl) ruthenium, derivatives thereof, or combinations thereof. In some embodiments, other ruthenium-containing compounds include tris(2,2,6,6-tetramethyl-3,5-heptanedionato) ruthenium, dicarbonyl pentadienyl ruthenium, ruthenium acetyl acetonate, (2,4-dimethylpentadienyl) ruthenium (cyclopentadienyl), bis(2,2,6,6-tetramethyl-3,5-heptanedionato) ruthenium (1,5-cyclooctadiene), (2,4-dimethylpentadienyl) ruthenium (methylcyclopentadienyl), (1,5-cyclooctadiene) ruthenium (cyclopentadienyl), (1,5-cyclooctadiene) ruthenium (methylcyclopentadienyl), (1,5-cyclooctadiene) ruthenium (ethylcyclopentadienyl), (2,4-dimethylpentadienyl) ruthenium (ethylcyclopentadienyl), (2,4-dimethylpentadienyl) ruthenium (isopropylcyclopentadienyl), bis(N,N-dimethyl 1,3-tetramethyl diiminato) ruthenium (1,5-cyclooctadiene), bis(N,N-dimethyl 1,3-dimethyl diiminato) ruthenium (1,5-cyclooctadiene), bis(allyl) ruthenium (1,5-cyclooctadiene), (η⁶-C₆H₆) ruthenium (1,3-cyclohexadiene), bis(1,1-dimethyl-2-aminoethoxylato) ruthenium (1,5-cyclooctadiene), bis(1,1-dimethyl-2-aminoethylaminato) ruthenium (1,5-cyclooctadiene), derivatives thereof, or combinations thereof. The preferred ruthenium-containing precursor used to deposit a catalytic layer is ruthenocene or ruthenium tetroxide.

Ruthenium deposition processes and soak processes that may be used during thermal or plasma-enhanced vapor deposition processes as described herein include commonly assigned U.S. Pat. No. 6,797,340, commonly assigned U.S. Ser. No. 11/038,592, entitled “Methods for Depositing Tungsten Layers Employing Atomic Layer Deposition Techniques,” filed Jan. 19, 2005, and published as US 2006-0009034, commonly assigned U.S. Ser. No. 10/634,662, entitled “Ruthenium Layer Formation for Copper Film Deposition,” filed Aug. 4, 2003, and published as US 2004-0105934, commonly assigned U.S. Ser. No. 10/811,230, entitled “Ruthenium Layer Formation for Copper Film Deposition,” filed Mar. 26, 2004, and published as US 2004-0241321, commonly assigned U.S. Ser. No. 11/069,514, entitled “Reduction of Copper Dewetting by Ruthenium Flash,” and filed Mar. 1, 2005, commonly assigned U.S. Ser. No. 11/009,331, entitled “Ruthenium as an Underlayer for Tungsten Film Deposition,” and filed Dec. 10, 2004, commonly assigned U.S. Ser. No. 60/714,580, entitled “Atomic Layer Process for Ruthenium Materials,” and filed Sep. 6, 2005, and commonly assigned U.S. Ser. Nos. 60/733,574, 60/733,654, 60/733,655, 60/733,869, 60/733,870, each entitled “Apparatus and Process for Plasma-Enhanced Atomic Layer Deposition,” and each filed Nov. 4, 2005, are all herein incorporated by reference in their entirety.

Other catalytic metal-containing compounds substitute to deposit catalytic layers by vapor deposition processes include noble metals that deposit their respective noble metal layer, such as precursors containing palladium, platinum, cobalt, nickel, iridium, or rhodium. Palladium-containing precursors include, for example, bis(allyl) palladium, bis(2-methylallyl) palladium, (cyclopentadienyl) palladium (allyl), derivatives thereof, or combinations thereof. Suitable platinum-containing precursors include dimethyl platinum (cyclooctadiene), trimethyl platinum (cyclopentadienyl), trimethyl platinum (methylcyclopentadienyl), cyclopentadienyl platinum (allyl), methyl (carbonyl) platinum cyclopentadienyl, trimethyl platinum (acetylacetonato), bis(acetylacetonato) platinum, derivatives thereof, or combinations thereof. Suitable cobalt-containing precursors include bis(cyclopentadienyl) cobalt, (cyclopentadienyl) cobalt (cyclohexadienyl), cyclopentadienyl cobalt (1,3-hexadienyl), (cyclobutadienyl) cobalt (cyclopentadienyl), bis(methylcyclopentadienyl) cobalt, (cyclopentadienyl) cobalt (5-methylcyclopentadienyl), bis(ethylene) cobalt (pentamethylcyclopentadienyl), derivatives thereof, or combinations thereof. A suitable nickel-containing precursor includes bis(methylcyclopentadienyl) nickel and suitable rhodium-containing precursors include bis(carbonyl) rhodium (cyclopentadienyl), bis(carbonyl) rhodium (ethylcyclopentadienyl), bis(carbonyl) rhodium (methylcyclopentadienyl), bis(propylene) rhodium, derivatives thereof, or combinations thereof.

In another exemplary vapor deposition process, a deposition gas containing a ruthenocene and nitrogen carrier gas is exposed to the reducing layer containing P—Hₓ functional groups formed by a phosphine soak process. The substrate is maintained at a temperature of about 350° C. After exposing the reducing layer to the ruthenium precursor containing gas for about 60 seconds, a ruthenium phosphide layer is formed on the barrier layer.

Liquid Deposition Processes

In another embodiment, a liquid deposition process may alternatively be used to deposit catalytic layer 208 on barrier layer 204, instead of a vapor deposition process. A liquid deposition process exposes reducing layer 206 to a deposition solution containing at least one catalytic metal-containing precursor and a solvent. Preferably, the liquid deposition process contains the catalytic metal-containing precursor dissolved in an aqueous solution.

The deposition solution may be prepared by combining at least one catalytic metal-containing precursor and a solvent. A catalytic metal-containing precursor is generally a salt of the respective catalytic metal desired to be deposited, such as the metal halides or the metal nitrates of ruthenium, cobalt, rhodium, iridium, nickel, palladium, and platinum. Other catalytic precursor salts include sulfates, nitrates, acetates, or other soluble derivatives of the catalytic metal. Preferably, the catalytic metal-containing precursor may include ruthenium chloride (Ru₃Cl₂), rhodium chloride, palladium chloride, platinum chloride, ruthenium nitrate, cobalt nitrate, rhodium nitrate, iridium nitrate, nickel nitrate, palladium nitrate, platinum nitrate, derivatives thereof, or combinations thereof. Although most, if not all, of the precursor may be dissolved within the deposition solution, the solution may also contain suspended particulate of the precursors. In one example, a dilute aqueous solution of ruthenium tetroxide may be used during process described herein. The solvent is preferably de-ionized water, and may also include one or more acidic or basic additives to alter the pH value as well as to act as a complexing agent to modulate the reactivity and achieve high selectivity. Organic solvents may be used instead of water or in combination with water. In general, process that use solutions containing the more expensive platinum group metals, it may be preferable to insure efficient metal utilization by using dilute solutions and employing a thin film puddle mode for minimizing the volume of used solution. The catalytic metal-containing precursor may be dissolved in the solvent at a concentration within a range from about 0.01 mM to about 50 mM. An acid may be added to the deposition solution. Acids may be organic acids, but preferably are inorganic acids such as hydrochloric acid, sulfuric acid, phosphoric acid, or nitric acid. The deposition solution is usually acidic and adjusted to have a pH value within a range from about 0.5 to about 5, preferably, from about 1 to about 3.

An example of a suitable deposition solution is one prepared by adding about 0.1 mL of a 10 wt % ruthenium chloride in 10% hydrochloric acid to 1 L of deionized water. In another example, a deposition solution contains about 20 ppm of palladium nitrate in 10 wt % nitric acid to 1 L of deionized water to provide a pH value within a range from about 1.5 to about 3.

The substrate is positioned in a process chamber commonly used for electroless- or electrochemical plating processes. One such process chamber is an electroless deposition process cell, further described in commonly assigned U.S. Ser. No. 10/965,220, entitled “Apparatus for Electroless Deposition,” filed on Oct. 14, 2004, and published as US 2005-0081785, in commonly assigned U.S. Ser. No. 60/539,491, entitled “Apparatus for Electroless Deposition of Metals on Semiconductor Wafers,” and filed on Jan. 26, 2004, in commonly assigned U.S. Ser. No. 60/575,553, entitled “Face Up Electroless Plating Cell,” and filed on May 28, 2004, commonly assigned U.S. Ser. No. 10/996,342, entitled “Apparatus for Electroless Deposition of Metals onto Semiconductor Substrates,” filed on Nov. 22, 2004, and published as US 2005-0160990, commonly assigned U.S. Ser. No. 11/043,442, entitled “Apparatus for Electroless Deposition of Metals onto Semiconductor Substrates,” filed on Jan. 26, 2005, and published as US 2005-0263066, commonly assigned U.S. Ser. No. 11/175,251, entitled “Apparatus for Electroless Deposition of Metals onto Semiconductor Substrates,” filed on Jul. 6, 2005, and published as US 2005-0260345, and commonly assigned U.S. Ser. No. 11/192,993, entitled “Apparatus for Electroless Deposition of Metals onto Semiconductor Substrates,” filed on Jul. 29, 2005, which are each incorporated by reference to the extent not inconsistent with the claimed aspects and description herein. Both the substrate and metal precursor solution are maintained at room temperature. The deposition solution is exposed to the substrate for a period of time from about 1 second to about 60 seconds, preferably from about 5 seconds to about 30 seconds. The reducing function on the surface of the barrier layer chemical reduces the catalytic metal-containing precursor to form the catalytic layer on the barrier layer with the adhesion promoted by the oxidation products of the reducing layer. For example, if the layer is formed using phosphine, it is believed that a phosphorus hydrogen metal (P—H-M) bond, a phosphorus metal (P-M) bond or a phosphorus oxygen metal (P—O-M) bond may be formed to increase adhesion.

After completing step 106 (or step 306 described below), the substrate may be annealed to help reduce the stress in deposited catalytic layer 208, recrystallize the formed catalytic layer 208, assure complete reaction between the catalytic and reducing layers, and/or outgas any water moisture from the substrate surface. The annealing process may be performed on the substrate by use of a resistive heater or by heat lamps. In one embodiment, the substrate is annealed at a temperature within a range from about 150° C. to about 600° C. The substrate may be annealed in a vacuum and/or a gas environment (e.g., Ar, He, N₂, N₂H₄, and/or H₂ environment). Preferably, the substrate is annealed in a vacuum environment. In one aspect the anneal step is performed in the same chamber as the catalytic layer 208 is formed. In another aspect, the anneal step is performed in a separate chamber that is attached to a cluster tool that is able to transfer the substrate in an inert, non-contaminating or non-oxidizing environment (e.g., under vacuum or inert gas environment) from the catalytic layer deposition chamber to the anneal chamber.

In an exemplary liquid deposition process, a deposition solution containing 5 mM of palladium nitrate diluted in nitric acid is dissolved in water and is exposed to the reducing layer. The reducing layer contains P—P and P—Hₓ functional groups after being treated phosphine plasma soak process. The substrate is maintained at a room temperature to deposit a palladium layer on the barrier layer.

In one aspect of the invention, the process step 106 is used to create a thick catalytic metal layer to allow electroplating deposition processes to be performed. The thickness of catalytic layer 208 formed during the process is thus greater than is necessary to react with the reducing layer 206. In one example, a ruthenium layer is deposited using a ruthenium tetroxide containing gas and a hydrogen containing gas at room temperature to form a layer that has a thickness within a range from about 10 Å to about 50 Å.

Conductive Layer Formation

Process 100 further includes step 108 to deposit a conductive layer on catalytic layer 208. Seed layer 210 in FIG. 2E or bulk layer 220 in FIG. 2F may be deposited on catalytic layer 208 as a conductive layer. In FIG. 2E, seed layer 210 is deposited as the conductive layer on catalytic layer 208. Seed layer 210 may be a continuous or a discontinuous layer deposited by using conventional deposition techniques, such as ALD, CVD, PVD, electroless, or electroplating. Seed layer 210 may have a thickness within a range from about a single molecular layer to about 100 Å. Generally, seed layer 210 contains copper, ruthenium, cobalt, tantalum, tungsten, aluminum, an alloy thereof, or a metal known to exhibit strong adhesion between bulk layer 220 and seed layer 210. In one example, seed layer 210 contains copper seed and is deposited by an electroless deposition process. In another example, seed layer 210 contains ruthenium or a ruthenium alloy and may be deposited by a CVD process, an ALD process, or a PVD process.

In FIG. 2F, bulk layer 220 is deposited as the conductive layer on catalytic layer 208. Bulk layer 220 may contain copper or a copper alloy deposited by using an electroless copper plating process alone or in combination with a deposition technique, such as a CVD process, an ALD process, a PVD process, or an electrochemical plating process. Bulk layer 220 may have a thickness within a range from about 100 Å to about 10,000 Å. In one example, bulk layer 220 contains copper and is deposited by an electroless copper plating process.

Alternatively, a conductive layer may include a secondary barrier layer, a conductive seed layer, or a copper adhesion layer deposited on the catalytic layer (not shown). The secondary barrier layer may be used as an underlayer before depositing an additional conductive layer, such as seed layer 210 and/or bulk layer 220. The seed layer may inhibit further copper diffusion into the dielectric or other portions of the substrate and reduces the chance of copper electromigration. A cobalt-containing alloy may be used as a secondary barrier layer and contain cobalt, nickel, tungsten, alloys thereof, which includes tungsten, molybdenum, ruthenium, phosphorus, boron, or combinations thereof, which are deposited by electroless plating processes.

Dielectric Deposition Process

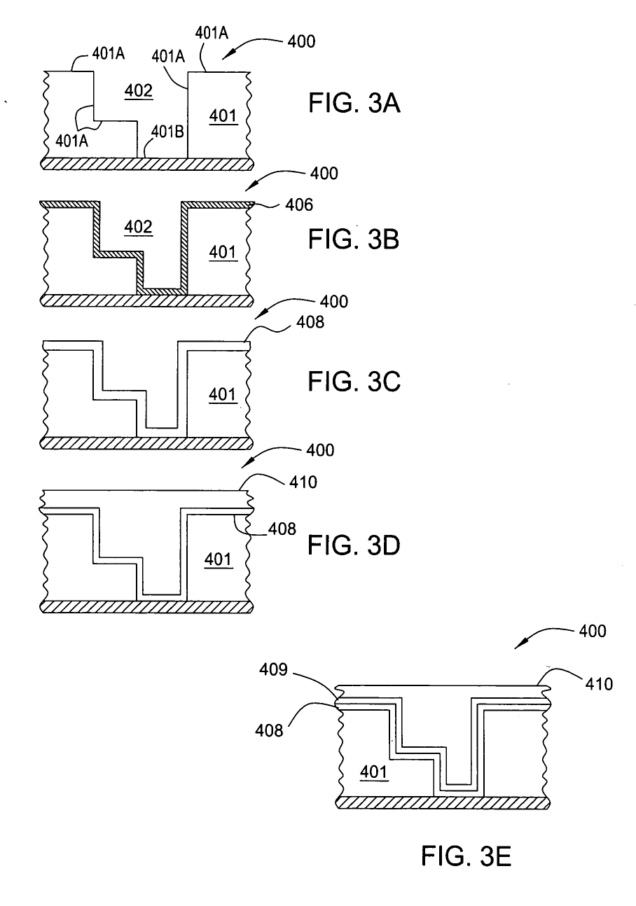

FIG. 1B depicts process 300 according to one embodiment described herein for fabricating an integrated circuit. Process 300 includes steps 302-306, wherein a catalytic layer is directly deposited on a dielectric surface 401A and contact surface 401B, as illustrated in FIGS. 3A-E. FIGS. 3A-E illustrate schematic cross-sectional views of an electronic device at different stages of an interconnect fabrication sequence, which incorporates at least one embodiment of the invention.

FIG. 3A illustrates a cross-sectional view of substrate 400 having a via or an aperture 402 formed in a dielectric layer 401 on the surface of the substrate 400. Process 300 begins by forming a reducing layer 406 on the dielectric layer 401 during step 302 by exposing the surface of the substrate 400 to a reducing plasma (see FIG. 3B). Subsequently in step 304, a catalytic layer 408 is deposited on the dielectric layer 401 by reacting a metal-containing catalytic precursor to the reducing layer 406 (see FIG. 3C). Thereafter, a conductive layer 410 is deposited on the catalytic layer 408 during step 306 (see FIG. 3D). FIG. 3E illustrates one aspect, where a second layer 409 is deposited on the catalytic layer 408 before the conductive layer 410 is deposited thereon. The second layer 409 may be added to act as a second barrier layer over the catalytic layer 408. In one example, the second layer 409 is a cobalt-containing layer.

The surface of dielectric surface 401A is generally an oxide and/or a nitride material containing silicon. However, the dielectric surface 401 A may contain an insulating material such as, silicon oxide, silicon nitride, silicon oxynitride, fluorine-doped silicate glass (FSG), or carbon-doped silicon oxides, such as SiOₓC_{y}, for example, BLACK DIAMOND® low-k dielectric, available from Applied Materials, Inc., located in Santa Clara, Calif. The contact surface 401B is an exposed region of the underlying interconnect in the lower layer and typically may contain materials, such as, copper, tungsten, ruthenium, CoWP, CoWPB, aluminum, aluminum alloys, doped silicon, titanium, molybdenum, tantalum, nitrides, or suicides thereof. Process 300 includes step 302, wherein a reducing layer is formed on the dielectric surface 401A and contact surface 401B by a plasma soak process. The plasma soak process includes exposing the substrate surface to a reducing plasma (i.e., a volatile reducing precursor or derivative thereof in the plasma state of matter) to form a reducing layer. The volatile reducing precursor in a plasma state may include borane, diborane, alkyboranes (e.g., ethylborane), phosphine, alkylposphines (e.g., dimethylphosphine), silane, disilane, trisilane, alkylsilanes (e.g., methylsilane), ammonia, hydrazine, hydrogen, complexes thereof, derivatives thereof, or combinations thereof. Preferably, the volatile reducing precursor is silane, diborane, phosphine or combinations thereof. A reducing layer may contain a layer of a chemically reducing molecular group, such as Si—Si, B—B, P—P, Si—Hₓ, B—Hₓ, and/or P—Hₓ. For example, phosphine may be used as a volatile reducing precursor to form reducing layer 206 having the functionalized groups of P—P, P—H, and/or PH₂ during a plasma soak process. In another example, diborane may be used as a volatile reducing precursor to form reducing layer 206 having the functionalized groups of B—B, B—H, and/or BH₂ during a plasma soak process. In another example, silane may be used as a volatile reducing precursor to form reducing layer 206 having the functionalized groups of Si—Si, Si—H, SiH₂, and/or SiH₃ during a plasma soak process.

The plasma soak process in step 302 may be conducted in a process chamber capable of plasma vapor deposition techniques. For example, the substrate may be placed into a PE-ALD, PE-CVD, or HDP-CVD chamber, such as, the ULTIMA HDP-CVD®, available from Applied Materials, Inc., located in Santa Clara, Calif. FIG. 4, discussed below, illustrates one embodiment of a capacitively coupled plasma chamber that may be useful for performing the plasma soak process described in step 302. In other aspects of the invention an inductively coupled plasma generating device, capacitively coupled plasma generating device, or combination thereof may be used in a plasma processing chamber to carryout the plasma soak process. The dielectric surface 401A is exposed to the plasma soak process for a pre-determined time to form a reducing layer. The plasma soak process may occur for about 5 minutes or less, such as within a range from about 1 second to about 60 seconds, preferably, from about 1 second to about 30 seconds. During the soak process, the substrate 400 is maintained at a temperature within a range from about 20° C. to about 150° C., preferably from about 50° C. to about 100° C. The process chamber is maintained at a pressure within a range from about 0.1 Torr to about 750 Torr, preferably, from about 1 Torr to about 100 Torr, and more preferably, from about 10 Torr to about 30 Torr.

The dielectric layer 401 is exposed to a reducing plasma containing the volatile reducing precursor to form the reducing layer thereon. The volatile reducing precursor is preferably diluted in a carrier gas containing, for example, argon and/or helium. During the plasma soak process in step 302, a carrier gas flow is established within the process chamber and exposed to the substrate. Carrier gases may be selected so as to also act as a purge gas for the removal of volatile reactants and/or by-products from the process chamber. Carrier gases or purge gases include helium, argon, hydrogen, forming gas, or a combination thereof. The carrier gas may be provided having a flow rate within a range from about 100 sccm to about 5,000 sccm, preferably, from about 500 sccm to about 2,500 sccm. The volatile reducing precursor may be provided having a flow rate within a range from about 5 sccm to about 500 sccm, preferably, from about 10 sccm to about 100 sccm. The plasma may be formed using an RF power delivered to the plasma generating devices (e.g., showerhead 411 in a capacitively coupled chamber 450, a substrate pedestal 415) utilized within the plasma chamber. Generally, the plasma chamber may be set during a plasma soak process to have a RF power within a range from about 100 watt to about 10,000 watt and have an RF frequency within a range from about 0.4 kHz to about 10 GHz. In one example, the plasma is formed using a showerhead RF power setting and a substrate support RF power setting that is within a range from about 500 watt to about 5,000 watt at a frequency of about 13.56 MHz.

In an exemplary plasma soak process, the substrate is heated to about 50° C. and the process chamber is maintained at a pressure of about 10 Torr. A reducing plasma is exposed to the substrate at a flow rate of about 500 sccm, whereas the reducing plasma contains diborane at a flow rate of about 50 sccm and an argon carrier gas at the flow rate of about 450 sccm. The substrate is exposed to the reducing plasma for about 30 seconds to form a reducing layer containing a layer of B—Hₓ functional groups on the dielectric layer.

In another exemplary plasma soak process, the substrate is heated to about 50° C. and the process chamber is maintained at a pressure of about 10 Torr. A reducing plasma is exposed to the substrate at a flow rate of about 1,000 sccm, whereas the reducing plasma contains phosphine at a flow rate of about 200 sccm and a helium carrier gas at the flow rate of about 800 sccm. The substrate 400 is exposed to the reducing plasma for about 60 seconds to form a reducing layer containing a layer of P—Hₓ functional groups on the dielectric layer.

In step 304, catalytic layer 408 is deposited on the dielectric layer 401 by exposing reducing layer 406 to a catalytic metal-containing precursor. The reducing layer chemically reduces the catalytic metal-containing precursor to form a catalytic layer on the dielectric layer 401 containing the respective metal from the precursor. In one example, the catalytic metal-containing precursor is delivered to the reducing layer 406 by a vapor deposition process, such as an ALD process or a CVD process. Alternatively, in another example, the catalytic metal-containing precursor is delivered to the reducing layer 406 by a liquid deposition process, such as an aqueous solution containing the precursor dissolved therein.

Catalytic layer 408 includes at least one catalytic metal and usually contains the oxidized remnants of the reducing layer 406. Catalytic layer 408 exhibits good adhesion to metal layers deposited onto the catalytic layer, such as copper, and also exhibits good adhesion to the oxidized remnants of the reducing layer 406. The catalytic metal may include ruthenium, cobalt, rhodium, iridium, nickel, palladium, platinum, silver, copper, alloys thereof, or combinations thereof. Generally, the chemical reaction between the reducing layer and the catalytic metal-containing precursor forms the metallic form of the catalytic metal (e.g., Ru⁰ or Co⁰) and/or the respective boride or phosphide, or combinations thereof. Therefore, the catalytic layer may contain ruthenium, ruthenium boride, ruthenium phosphide, copper, cobalt, cobalt boride, cobalt phosphide, rhodium, rhodium boride, rhodium phosphide, iridium, iridium boride, iridium phosphide, nickel, nickel boride, nickel phosphide, palladium, palladium boride, palladium phosphide, platinum, platinum boride, platinum phosphide, derivatives thereof, alloys thereof, or combinations thereof. The catalytic layer 408 is deposited with a thickness within a range from about an atomic layer to about 100 Å, preferably, from about 5 Å to about 50 Å, for example, about 10 Å. The catalytic layer 408 adheres to the dielectric layer 401 as well as the subsequent conducting layer, such as a seed layer or a bulk layer.

During a vapor deposition process, the catalytic metal-containing precursor is vaporized and exposed to the reducing layer 406. The vapor deposition process is conducted at a temperature high enough to vaporize the catalytic metal-containing precursor and drive the reduction reaction to completion. However, the process temperature is low enough not to cause the catalytic metal-containing precursor to prematurely thermally decompose, such as in the delivery lines or on the process chamber interior. The temperature range various according to the particular catalytic metal-containing precursor used during the deposition. Generally, the temperature is maintained within a range from about 25° C. to about 250° C., preferably from about 50° C. to about 100° C. The process chamber may be a typical vapor deposition chamber as used during ALD, CVD, or PVD processes. The process chamber is maintained at a pressure relative to the temperature, precursor and particular process. Generally, the pressure is maintained within a range from about 0.1 Torr to about 750 Torr, preferably from about 1 Torr to about 200 Torr. The catalytic metal-containing precursor is exposed to a reducing layer for a predetermined time interval within a range from about 0.1 second to about 5 minutes, preferably from about 1 second to about 120 seconds, and more preferably, from about 5 seconds to about 90 seconds. The catalytic metal-containing precursor may be delivered purely or diluted in a carrier gas that includes nitrogen, hydrogen, argon, helium, or combinations thereof.

Catalytic metal-containing precursors may include the ruthenium-containing precursors and the other metal precursors as discussed in step 106. In one example, the catalytic metal-containing precursor is combined with an inert gas as a mixture. The mixture and a hydrogen-containing gas are separately delivered to the processing region of the processing chamber to form the catalytic layer. Preferably, the ruthenium precursors include ruthenium tetroxide, ruthenocene, and other ruthenocene compounds.

In an exemplary vapor deposition process, a deposition gas containing ruthenocene and nitrogen carrier gas is exposed to the reducing layer 406. The reducing layer contains B—Hₓ functional groups after being treated with a diborane soak process. The substrate is maintained at a temperature of about 200° C. A ruthenium boride layer is deposited on the dielectric layer after about 60 seconds. In one embodiment, the substrate surface may be exposed to additional cycles of diborane and ruthenocene to form a barrier layer or a seed layer during an ALD process. Thereafter, an additional material may be deposited on the substrate surface during a subsequent process, such as, an electrochemical plating (ECP) process.

In another exemplary vapor deposition process, a deposition gas is formed by exposing a flow on ozone to a ruthenium source. The deposition gas containing ruthenium tetroxide and an argon carrier gas is exposed to the reducing layer 406. The reducing layer contains P—Hₓ functional groups after being treated with a phosphine soak process. The substrate is maintained at a temperature of about 100° C. After exposing the reducing layer to the ruthenium tetroxide containing gas for about 30 seconds a ruthenium oxide on a phosphate layer is formed on the substrate surface. The ruthenium oxide layer may be useful as a catalytic layer during a subsequent electroless deposition process.

Embodiments of step 304 that use a liquid deposition process to form the catalytic layer 408 are described above in conjunction with process step 106 of process 100. In another embodiment, the catalytic layer 408 and the conductive layer 410 (e.g., metal seed or fill material) may both be formed on a substrate during a single electroless deposition process. The catalytic layer 408 and the conductive layer 410 may have the same or different compositions and may be formed as a single layer or as two or more distinct layers. The reducing layer 406 may be exposed to an electroless deposition solution to form the catalytic layer 408 at the beginning of the electroless deposition process and subsequently, the conductive layer 410 may be deposited thereon. In one example, a phosphine plasma activated barrier layer (e.g., tantalum nitride or tantalum nitride/tantalum) covering a damascene pattern is exposed to an electroless copper plating solution to deposit a copper-containing catalytic layer and a copper-containing conductive layer. The electroless plating bath provides the source of the soluble metal precursor (e.g., copper), as well as components for promoting the autocatalytic growth of a copper material over the catalytic layer 408. The catalytic layer 408 and the conductive layer 410 may independently contain copper, nickel, cobalt, tungsten, tantalum, alloys thereof, or combinations thereof.

Process 300 further includes step 306 to deposit a conductive layer 410 on the catalytic layer 408. The conductive layer 410 may form a seed layer (e.g., a thin metal layer) or a bulk layer (e.g., fill the aperture 402 (see FIG. 3D)) that is deposited on the catalytic layer 408. Preferably, a seed layer is a continuous layer of material deposited by using conventional deposition techniques, such as an ALD process, a CVD process, a PVD process, or an electroless deposition process. Alternatively, the seed layer may be a discontinuous layer. Seed layers may have a thickness within a range from about a single molecular layer to about 100 Å, preferably, from about 20 Å to about 100 Å. Generally, a seed layer contains copper or a copper alloy.

In another example, conductive layer 410, such as a bulk layer, may be deposited on catalytic layer 408, as depicted in FIG. 3D. A bulk layer may contain copper or a copper alloy deposited by using conventional deposition techniques, such as an electroless deposition process or an electrochemical plating process. A bulk layer may have a thickness within a range from about 100 Å to about 10,000 Å. In one example, a copper-containing bulk layer is deposited by an electroplating deposition process.

Alternatively, a conductive layer may include second layer 409, such as a secondary barrier layer, may be deposited on catalytic layer 408, as depicted in FIG. 3E. A secondary barrier layer may be used as an underlayer before depositing a secondary conductive layer, such as a seed layer and/or a bulk layer. A secondary barrier layer further prevents copper diffusion into the dielectric or other portions of the substrate. A cobalt-containing alloy may be used as a secondary barrier layer and include cobalt, cobalt tungsten, cobalt tungsten phosphide, cobalt tungsten boride, cobalt tungsten boro-phosphide, derivatives there of, or combinations thereof. A more detailed description of self-activating electroless deposition that may used to deposit a secondary barrier containing cobalt may be found in the commonly assigned U.S. Ser. No. 10/967,919, entitled “Selective Self-Initiating Electroless Capping Of Copper With Cobalt-Containing Alloys,” filed Oct. 21, 2004, and published as US 2005-0136193, which is incorporated by reference herein in its entirety to the extent not inconsistent with the claimed aspects and description herein.

In an alternative embodiment, a direct process to deposit a ruthenium-containing catalytic layer used during integrated circuit fabrication is described herein. The direct process includes depositing a ruthenium-containing catalytic layer directly on a dielectric surface and a contact surface. The direct process is similar to process 300 absent the underlying barrier layer but including exposure to a reducing plasma. The exposure to a volatile reducing agent or plasma may also be omitted for some precursors. For example, a ruthenium-containing layer may be deposited by exposing the dielectric surface directly to a deposition gas containing ruthenium tetroxide. The ruthenium tetroxide may be generated via the in situ process as described herein. The dielectric layer is exposed to the deposition gas containing ruthenium tetroxide for a period of time from about 5 seconds to about 5 minutes, preferably from about 10 seconds to about 2 minutes, and more preferably from about 30 seconds to about 90 seconds. Thereafter, a conductive layer (e.g., seed layer or a bulk layer) may be deposited on the ruthenium-containing catalytic layer as discussed in process 300.

Hardware Design

Plasma Process Chamber

FIG. 4 illustrates a capacitively coupled plasma chamber 450. A sidewall 405, a ceiling 403 and a base 407 enclose the capacitively coupled plasma chamber 450 and form a process area 421. A substrate pedestal 415, which supports a substrate 422, mounts to the base 407 of the capacitively coupled plasma chamber 450. A backside gas supply (not shown) furnishes a gas, such as helium, to a gap between the backside of the substrate 422 and the substrate pedestal 415 to improve thermal conduction between the substrate pedestal 415 and the substrate 422. In one embodiment, the substrate pedestal 415 is heated and/or cooled by use of a heat exchanging device 416 and temperature controller 417, to improve the plasma process results on the substrate 422 surface. In one embodiment the heat exchanging device 416 is an fluid heat exchanging device that contains embedded heat transfer fluid lines (not shown) that are in communication with a fluid temperature controlling device (not shown). In another aspect, the heat exchanging device 416 is a thermoelectric device that is adapted to heat and cool the substrate pedestal 415.

A vacuum pump 435 controls the pressure within the capacitively coupled plasma chamber 450, typically holding the pressure below 0.5 milliTorr (mTorr). A gas distribution showerhead 411 has a gas distribution plenum 420 connected to the inlet line 426 and the process gas supply 425. The inlet line 426 and gas supply 425 are in communication with the process region 427 over the substrate 422 through plurality of gas nozzle openings 430. The showerhead 411, made from a conductive material (e.g., anodized aluminum), acts as a plasma controlling device by use of the attached to a first impedance match element 475 and a first RF power source 490. A bias RF generator 462 applies RF bias power to the substrate pedestal 415 and substrate 422 through an impedance match element 464. A controller 480 is adapted to control the impedance match elements (i.e., 475 and 464), the RF power sources (i.e., 490 and 462) and all other aspects of the plasma process. In one embodiment dynamic impedance matching is provided to the substrate pedestal 415 and the showerhead 411 by frequency tuning and/or by forward power serving. While FIG. 4 illustrates a capacitively coupled plasma chamber, other embodiments of the invention may include inductively coupled plasma chambers or a combination of inductively and capacitively coupled plasma chambers without varying from the basic scope of the invention.

Fluid Process Chambers

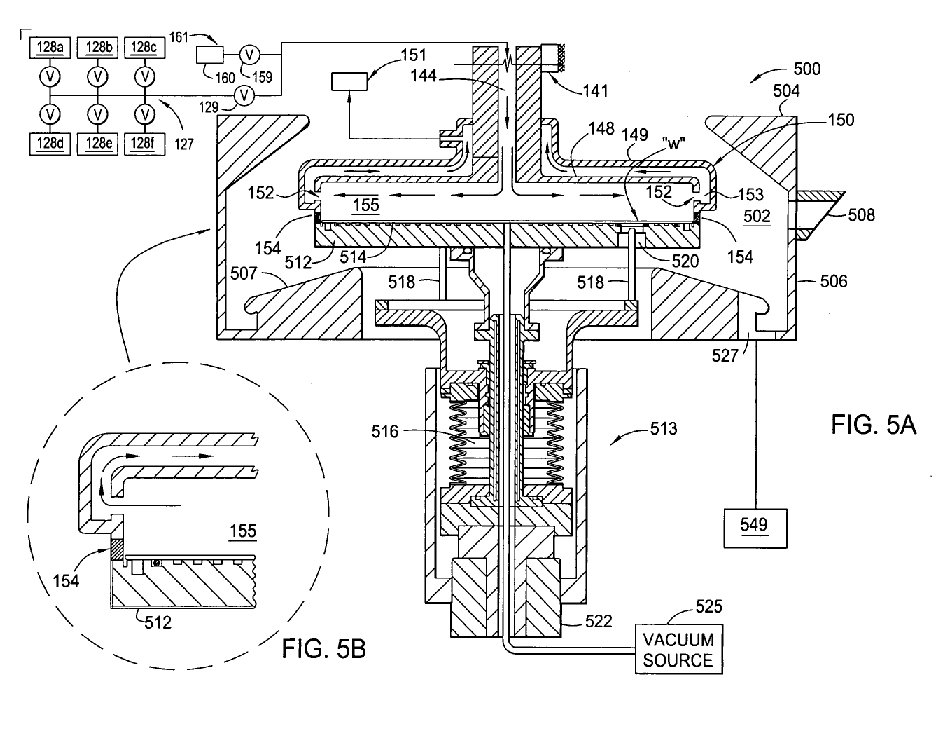

FIGS. 5A and 5B illustrate a schematic cross-sectional view of one embodiment of a fluid processing cell 500 that may be useful -to deposit the conductive layer(s) using an electroless or electroplating process as described herein. The fluid processing cell 500 includes a processing compartment 502 containing a top 504, sidewalls 506, a processing shield 150 and a bottom 507. A substrate support 512 is disposed in a generally central location in the fluid processing cell 500. The substrate support 512 includes a substrate receiving surface 514 to receive the substrate “W” in a “face-up” position. A vacuum source 525, such as a vacuum pump, is in fluid communication with processing region 155.

The substrate support 512 may contain a ceramic material (such as alumina Al₂O₃ or silicon carbide (SiCₓ)), TEFLON® coated metal (such as aluminum or stainless steal), a polymer material, or other suitable materials. TEFLON® as used herein is a generic name for fluorinated polymers such as TEFZEL® (ETFE), HALAR® (ECTFE), PFA, PTFE, FEP, PVDF, and derivatives thereof. Preferably, the substrate support 512 contains alumina. The substrate support 512 may further comprise embedded heated elements, especially for a substrate support containing a ceramic material or a polymer material. In one example, a plating solution is collected and recirculated across the surface of the substrate by use of source tank system 549, which is adapted to recirculate collected plating solution.

The fluid processing cell 500 further includes a slot 508 or opening formed through a wall thereof to provide access for a robot (not shown) to deliver and retrieve the substrate “W” to and from the fluid processing cell 500. Alternatively, the substrate support 512 may raise the substrate “W” through the top 504 of the processing compartment to provide access to and from the fluid processing cell 500.

A lift assembly 516 may be disposed below the substrate support 512 and coupled to lift pins 518 to raise and lower lift pins 518 through apertures 520 in the substrate support 512. The lift pins 518 raise and lower the substrate “W” to and from the substrate receiving surface 514 of the substrate support 512.

A motor 522 may be coupled to the substrate support 512 to rotate the substrate support 512 to spin the substrate “W”. In one embodiment, the lift pins 518 may be disposed in a lower position below the substrate support 512 to allow the substrate support 512 to rotate independently of the lift pins 518. In another embodiment, the lift pins 518 may rotate with the substrate support 512.

The substrate support 512 may be heated to heat the substrate “W” to a desired temperature. The substrate receiving surface 514 of the substrate support 512 may be sized to substantially receive the backside of the substrate “W” to provide uniform heating of the substrate “W”. Uniform heating of a substrate is an important factor in order to produce consistent processing of substrates, especially for deposition processes having deposition rates that are a function of temperature.

In one embodiment, a processing shield 150 is positioned opposite the substrate receiving surface 514 and is adapted to form a processing region 155 above the surface of the substrate. The processing region 155, when formed, is generally bounded by the surface of the substrate, and a seal 154 and a lower wall 148 of the processing shield 150. The processing shield 150 generally contains an injection port 144, a seal 154, a lower wall 148, an upper wall 149, an evacuation region 153 and a plurality of holes 152 through the lower wall 148 that connect the processing region 155 to the evacuation region 153.

In one aspect, the processing region 155 is formed when the processing shield 150 is translated so that the seal 154 of the processing shield 150 come into contact with the substrate receiving surface 514 of the substrate support 512. Movement, or translation, of the processing shield 150 may be performed by use of processing shield lift 141 that is adapted to raise and lower the processing shield 150 relative to the substrate surface. The processing shield lift 141 may also adapted to raise and lower the processing shield 150 so that a substrate can be transferred to and from the lift pins 518 by a robot (not shown) mounted outside the slot 508.

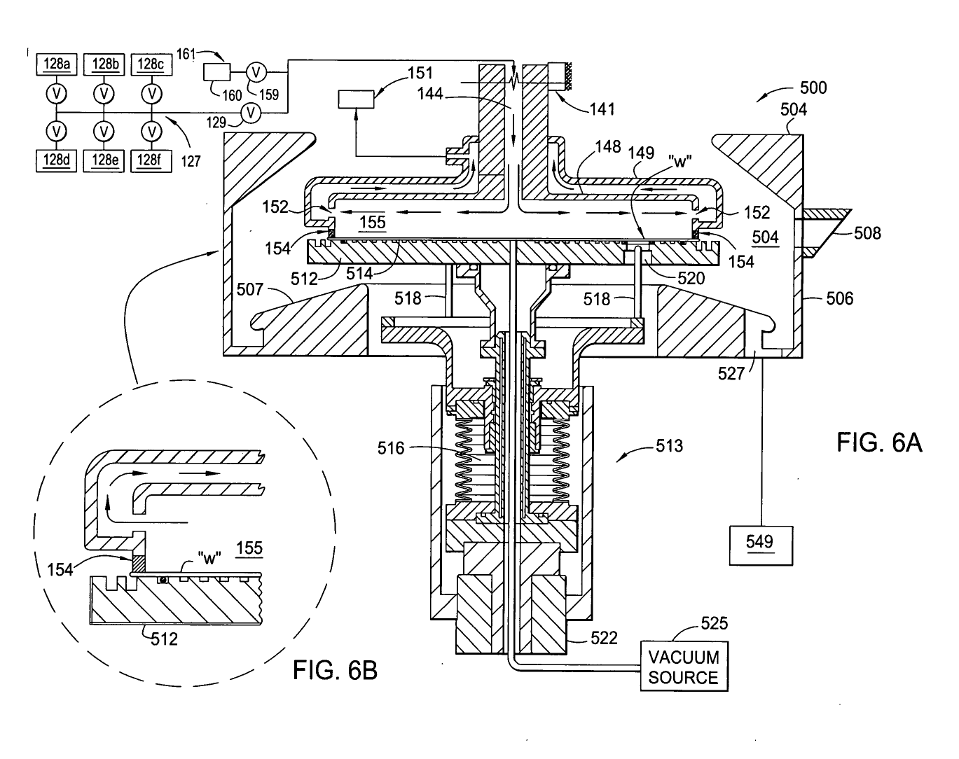

Referring to FIGS. 6A and 6B, in another aspect, the processing region 155 is formed when the processing shield 150 is translated so that the seal 154 of the processing shield 150 contacts the surface of the substrate “W”, thus forming a processing region 155 that is enclosed by the surface of the substrate “W” and the lower wall 148. For clarity the similar components shown in FIGS. 6A and 6B have retained the same item numbers as shown in FIGS. 5A and 5B.

During processing, the processing region 155 may be adapted to retain a processing fluid so that a desired processing step can be performed on the substrate surface. This configuration may be advantageous since it allows various processing fluids that may be incompatible with other processing chamber components to be contained in a controlled region, and also allows the processing conditions in the processing region 155 to be controlled to achieve improved process results. In one aspect, it may be desirable control, for example, the pressure, temperature, and flow rate of the processing fluid retained in the processing region 155. In one aspect, the processing shield may be heated to control the temperature of the processing fluid retained in the processing region 155. A resistive heating element (not shown) may be placed in thermal contact with the processing shield 150 may be used to heat the processing fluid retained in the processing region 155.

In one embodiment, a process gas source 161 containing a gas reservoir 160 and valve 159 and/or a liquid source 127 containing liquid reservoirs 128a-128f and valve 129 are adapted to deliver one or more processing fluids to the injection port 144, into the processing region 155, across the substrate surface, through the holes 152 and into the evacuation region 153 where the process gas is directed to the waste source system 151. The waste source system 151 may contain a pump (not shown) that is adapted to create a lower pressure in the evacuation region 153 to cause a flow of the processing fluid from the processing region 155 to the evacuation region 153 through the holes 152.

The fluid processing cell 500 further includes a drain 527 in order to collect and expel fluids used in the fluid processing cell 500. The bottom 507 of the processing compartment 502 may contain a sloped surface to aid the flow of fluids used in the fluid processing cell 500 towards an annular channel in communication with the drain 527 and to protect the substrate support assembly 513 from contact with fluids.

A more detailed description of face-up processing cell may be found in the commonly assigned U.S. Ser. No. 10/059,572, entitled “Electroless Deposition Apparatus,” filed Jan. 28, 2002, and published as US 2003-0141018, which is incorporated by reference herein in its entirety to the extent not inconsistent with the claimed aspects and description herein.

“Atomic layer deposition” (ALD) or “cyclical deposition,” as used herein, refers to the sequential introduction of two or more reactive compounds to deposit a layer of material on a substrate surface. The two, three or more reactive compounds may alternatively be introduced into a reaction zone of a processing chamber. Usually, each reactive compound is separated by a time delay to allow each compound to adhere and/or react on the substrate surface. In one aspect, a first precursor or compound A is pulsed into the reaction zone followed by a first time delay. Next, a second precursor or compound B is pulsed into the reaction zone followed by a second delay. During each time delay a purge gas, such as nitrogen, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, pulsing compound B and purge gas is a cycle. A cycle may start with either compound A or compound B and continue the respective order of the cycle until achieving a film with the desired thickness.

A “substrate surface,” as used herein, refers to any substrate or material surface formed on a substrate upon which film processing is performed. For example, a substrate surface on which processing may be performed include materials such as monocrystalline, polycrystalline or amorphous silicon, strained silicon, silicon on insulator (SOI), doped silicon, fluorine-doped silicate glass (FSG), silicon germanium, germanium, gallium arsenide, glass, sapphire, silicon oxide, silicon nitride, silicon oxynitride, or carbon doped silicon oxides, such as SiOₓC_{y}, for example, BLACK DIAMOND® low-k dielectric, available from Applied Materials, Inc., located in Santa Clara, Calif. Substrates may have various dimensions, such as 200 mm or 300 mm diameter wafers, as well as, rectangular or square panes. Embodiments of the processes described herein deposit metal-containing layers on many substrates and surfaces, especially, barrier layers, seed layers, and adhesions layers. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers, and patterned or non-patterned wafers. Substrates made of glass or plastic, which, for example, are commonly used to fabricate flat panel displays and other similar devices, may also be used during embodiments described herein.

A “pulse,” as used herein, is intended to refer to a quantity of a particular compound that is intermittently or non-continuously introduced into a reaction zone of a processing chamber. The quantity of a particular compound within each pulse may vary over time, depending on the duration of the pulse. The duration of each pulse is variable depending upon a number of factors such as, for example, the volume capacity of the process chamber employed, the vacuum system coupled thereto, and the volatility/reactivity of the particular compound itself. A “half-reaction,” as used herein, refers to a pulse of a precursor followed by a purge step.

Chamber Process Example

In one embodiment of process 100, the step 104 (e.g., forming a reducing layer) is performed in the fluid processing cell 500 just prior to completing the processing step 106, (e.g., forming a catalytic layer) in the fluid processing cell 500. In one example, the substrate is transferred into the fluid processing cell 500 and placed on the substrate receiving surface 514 by a robot (not shown) and the lift pins 518 during process 100. Next the processing shield 150 is then moved into position where it contacts the substrate receiving surface 514, or the substrate surface, to form the processing region 155. The pressure in the evacuation region 153, and processing region 155, is then lowered by use of the pump (not shown) in waste source system 151. A processing fluid is then delivered to the processing region 155 from a process gas source 161 that is connected to the injection port 144. In one example, the processing gas contains ruthenium tetroxide to form a ruthenium-containing layer on the surface of the substrate. The temperature of the substrate can be controlled to a temperature within a range from about 20° C. to about 100° C. by use of the embedded heating elements retained in the substrate support 512. The temperature of the processing fluid can be controlled by use of heating elements embedded in the processing shield (not shown) or heaters mounted on the piping (not shown) between the process gas source 161 and the processing region 155. During step 104 the processing gas may be halted for a desired period of time or the process gas may be continually flowed across the substrate surface.

After performing the step 104, the processing region 155 may then be purged with a carrier gas (e.g., argon or nitrogen) to remove any of the remnants of the processing gas. Next an electroless or electroplating solution may be delivered to the processing region 155 from the liquid source 127 so that a catalytic layer formation step 106 can be performed on the reducing layer on the substrate surface. One method and apparatus that may be used to perform an electroless deposition process of the catalytic layer on the reducing layer is further described in the commonly assigned U.S. Ser. No. 10/967,919, entitled “Selective Self-Initiating Electroless Capping Of Copper With Cobalt-Containing Alloys,” filed Oct. 21, 2004, and published as US 2005-0136193, and commonly assigned U.S. Ser. No. 11/040,962, entitled “Method and Apparatus For Selectively Changing Thin Film Composition During Electroless Deposition In A Single Chamber,” filed Jan. 22, 2005, and published as US 2005-0181226, which are both incorporated herein by reference in their entirety to the extent not inconsistent with the claimed aspects and the description herein.

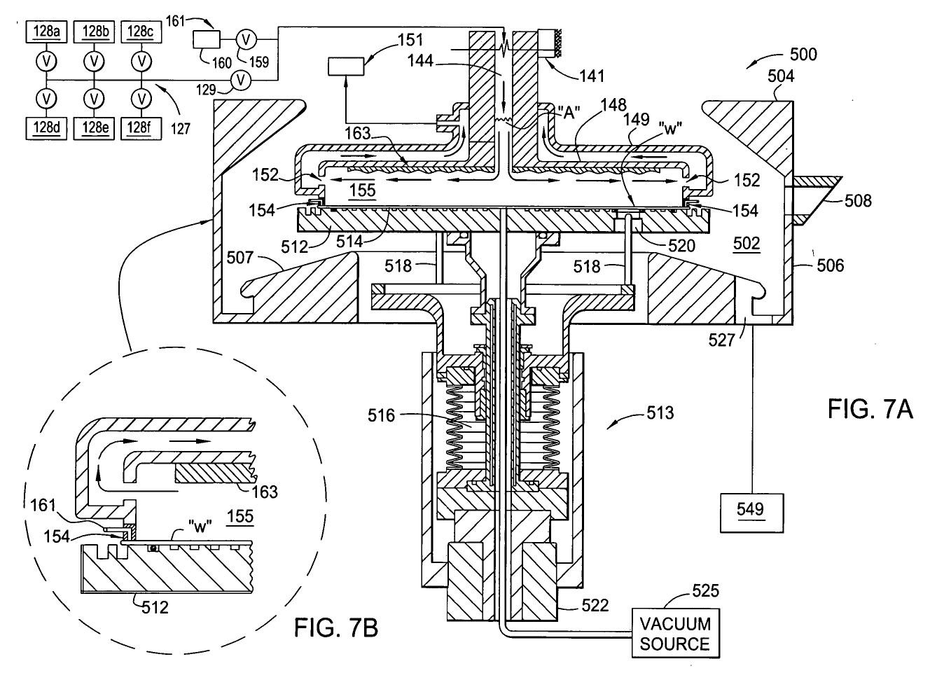

Referring to FIGS. 7A and 7B, in one embodiment of the fluid processing cell 500, one or more electrical contacts (not shown) are embedded in the seal 154 of the processing shield 150 and an anode 163 is placed in contact with the processing fluid (see item “A”) so that a plating current can be delivered to the reducing layer so that the catalytic layer can be deposited using an electroplating process. The metal ions in the processing fluid will be plated on the reducing layer by applying a negative bias to the reducing layer surface relative to the anode 163 by use of a power supply (not shown). In one aspect, the anode 163 is a consumable anode (e.g., a copper anode) that can replenish ions (e.g., copper ions) removed during the plating process. In one aspect, the anode 163 is a non-consumable anode, such as, a platinum anode, a platinum coated titanium anode, or a titanium anode, that does not replenish ions removed during the plating process.

The electroplating process may also be completed in a separate electroplating chamber. One method, apparatus and system that may be used to perform an electroplating deposition process is further described in the commonly assigned U.S. Ser. No. 10/268,284, entitled “Electrochemical Processing Cell,” filed Oct. 9, 2002, and published as US 2004-0016636, and U.S. Pat. No. 6,258,220, which are incorporated by reference herein in their entirety to the extent not inconsistent with the claimed aspects and description herein.

While foregoing is directed to the preferred embodiment of the invention, other and further embodiments of the invention may be devised without departing from the basic scope thereof, and the scope thereof is determined by the claims that follow.

1. A method for depositing a conductive material on a substrate, comprising:
exposing a substrate containing a barrier layer to a volatile reducing precursor to form a reducing layer thereon;
exposing the reducing layer to a catalytic-metal precursor to deposit a catalytic metal-containing layer on the barrier layer; and
depositing a conductive layer on the catalytic metal-containing layer.

2. The method of claim 1, wherein the barrier layer comprises tantalum nitride.

3. The method of claim 2, wherein the tantalum nitride is deposited on the substrate by an atomic layer deposition process within a process chamber.

4. The method of claim 3, wherein forming the reducing layer is formed within the process chamber.

5. The method of claim 4, wherein the volatile reducing precursor is selected form the group consisting of phosphine, diborane, silane, disilane, hydrogen, ammonia, hydrazine, derivatives thereof, plasmas thereof, and combinations thereof.

6. The method of claim 5, wherein the reducing layer comprises a functionalized surface selected from the group consisting of P—Hₓ, B—Hₓ, Si—Hₓ, derivatives thereof, and combinations thereof.

7. The method of claim 5, wherein forming the reducing layer comprises exposing the substrate to the volatile reducing precursor for a time period within a range from about 1 second to about 30 seconds.

8. The method of claim 4, wherein the catalytic metal-containing layer comprises an element selected from the group consisting of ruthenium, cobalt, rhodium, iridium, nickel, palladium, platinum, silver, copper, alloys thereof, and combinations thereof.

9. The method of claim 8, wherein the catalytic metal-containing layer is deposited by a vapor deposition process and the catalytic-metal precursor is selected from the group consisting of ruthenium tetroxide, ruthenocene, and derivatives thereof.

10. The method of claim 9, wherein the catalytic-metal precursor comprises ruthenium tetroxide formed by an in situ process containing ruthenium metal and an oxidizer.

11. The method of claim 8, wherein the catalytic metal-containing layer is deposited by a liquid deposition process and the catalytic-metal precursor is a salt selected from the group consisting of ruthenium chloride, cobalt chloride, palladium chloride, platinum chloride, and combinations thereof.

12. The method of claim 8, wherein the conductive layer comprises an element selected from the group consisting of copper, nickel, cobalt, tungsten, tantalum, alloys thereof, and combinations thereof.

13. The method of claim 1, wherein the reducing layer is exposed to an electroless solution to deposit the catalytic metal-containing layer and the conductive layer during a single process.

14. The method of claim 13, wherein the catalytic metal-containing layer and the conductive layer independently comprise a material selected from the group consisting of copper, nickel, cobalt, tungsten, tantalum, alloys thereof, and combinations thereof.

15. A method for depositing a conductive material on a substrate, comprising:
exposing a substrate containing a barrier layer to a volatile reducing precursor during a soak process;
depositing a catalytic metal-containing layer on the barrier layer, wherein the catalytic metal-containing layer comprises an element selected from the group consisting of ruthenium, cobalt, rhodium, iridium, nickel, palladium, platinum, silver, copper, alloys thereof, and combinations thereof; and
depositing a conductive layer on the catalytic metal-containing layer.

16. The method of claim 15, wherein the barrier layer comprises tantalum nitride.

17. The method of claim 16, wherein the tantalum nitride is deposited on the substrate by an atomic layer deposition process within a process chamber.

18. The method of claim 17, wherein the soak process is conducted within the process chamber.

19. The method of claim 15, wherein the volatile reducing precursor is selected form the group consisting of phosphine, diborane, silane, disilane, hydrogen, ammonia, hydrazine, derivatives thereof, plasmas thereof, and combinations thereof.

20. The method of claim 19, wherein the substrate is exposed to the volatile reducing precursor for a time period within a range from about 1 second to about 30 seconds during the soak process.

21. The method of claim 15, wherein the catalytic metal-containing layer is deposited by exposing the substrate to a catalytic-metal precursor during a vapor deposition process and the catalytic-metal precursor is selected from the group consisting of ruthenium tetroxide, ruthenocene, and derivatives thereof.

22. The method of claim 21, wherein the catalytic-metal precursor comprises ruthenium tetroxide formed by an in situ process containing ruthenium metal and an oxidizer.

23. The method of claim 15, wherein the catalytic metal-containing layer is deposited by exposing the substrate to a catalytic-metal precursor during a liquid deposition process and the catalytic-metal precursor is a salt selected from the group consisting of ruthenium chloride, cobalt chloride, palladium chloride, platinum chloride, and combinations thereof.

24. The method of claim 15, wherein the conductive layer comprises an element selected from the group consisting of copper, nickel, cobalt, tungsten, tantalum, alloys thereof, and combinations thereof.

25. The method of claim 15, wherein the substrate is exposed to an electroless solution to deposit the catalytic metal-containing layer and the conductive layer during a single process.

26. A method for depositing a conductive material on a substrate, comprising:
exposing a substrate containing a barrier layer to a volatile reducing precursor during a soak process;
exposing the substrate to a catalytic-metal precursor to deposit a catalytic metal-containing layer on the barrier layer during a vapor deposition process, wherein the catalytic-metal precursor is selected from the group consisting of ruthenium tetroxide, ruthenocene, and derivatives thereof; and
depositing a conductive layer on the catalytic metal-containing layer.

27. The method of claim 26, wherein the barrier layer is deposited by an atomic layer deposition process within a process chamber.

28. The method of claim 27, wherein the soak process is conducted within the process chamber.

29. The method of claim 26, wherein the substrate is exposed to the volatile reducing precursor for a time period within a range from about 1 second to about 30 seconds during the soak process.

30. The method of claim 29, wherein the volatile reducing precursor is selected form the group consisting of phosphine, diborane, silane, disilane, hydrogen, ammonia, hydrazine, derivatives thereof, plasmas thereof, and combinations thereof.

31. The method of claim 30, wherein the conductive layer comprises an element selected from the group consisting of copper, nickel, cobalt, tungsten, tantalum, alloys thereof, and combinations thereof.

32. A method for depositing a conductive material on a substrate, comprising:
exposing a substrate containing a barrier layer to a volatile reducing precursor during a soak process;
exposing the substrate to a catalytic-metal precursor to deposit a catalytic metal-containing layer on the barrier layer during a liquid deposition process, wherein the catalytic-metal precursor is a salt selected from the group consisting of ruthenium chloride, cobalt chloride, palladium chloride, platinum chloride, and combinations thereof; and
depositing a conductive layer on the catalytic metal-containing layer.

33. The method of claim 32, wherein the barrier layer is deposited by an atomic layer deposition process within a process chamber.

34. The method of claim 33, wherein the soak process is conducted within the process chamber.

35. The method of claim 32, wherein the substrate is exposed to the volatile reducing precursor for a time period within a range from about 1 second to about 30 seconds during the soak process.

36. The method of claim 35, wherein the volatile reducing precursor is selected form the group consisting of phosphine, diborane, silane, disilane, hydrogen, ammonia, hydrazine, derivatives thereof, plasmas thereof, and combinations thereof.

37. The method of claim 36, wherein the conductive layer comprises an element selected from the group consisting of copper, nickel, cobalt, tungsten, tantalum, alloys thereof, and combinations thereof.

38. The method of claim 32, wherein the substrate is exposed to an electroless solution to deposit the catalytic metal-containing layer and the conductive layer during a single process.

39. A method for depositing a conductive material on a substrate, comprising:
exposing a substrate containing an oxide layer to a reactive soak compound during a plasma process, wherein the reactive soak compound is derived from a precursor selected from the group consisting of phosphine, diborane, silane derivatives thereof, and combinations thereof;
exposing the substrate to ruthenium tetroxide during a vapor deposition process to deposit a catalytic metal-containing layer on the substrate; and
depositing a conductive layer on the catalytic metal-containing layer.

40. A method for depositing a conductive material on a substrate, comprising:
exposing a substrate containing a barrier layer to a volatile reducing precursor to form a phosphorus-containing reducing layer thereon; and
exposing the phosphorus-containing reducing layer to a catalytic-metal precursor to deposit a ruthenium-containing layer on the barrier layer.
